(19) United States
(12) Patent Application Publication
(10) Pub. No.: US 2024/0290668 A1
(43) Pub. Date: Aug. 29, 2024

(54) SEMICONDUCTOR DEVICE WITHOUT RESISTANCE TRIMMING PADS

(71) Applicant: PANJIT INTERNATIONAL INC., Kaohsiung City (TW)

(72) Inventors: CHUNG-HSIUNG HO, Kaohsiung City (TW); CHIA-WEI CHEN, Kaohsiung City (TW); SHAN-DE YANG, Taichung City (TW)

(21) Appl. No.: 18/298,799

(22) Filed: Apr. 11, 2023

(30) Foreign Application Priority Data
Feb. 23, 2023 (TW) 112106795

(51) Int. Cl. H01L 21/66; H01L 23/522

(52) U.S. Cl. CPC H01L 22/32; H01L 22/34; H01L 23/5228

(57) ABSTRACT

A semiconductor device without resistance trimming pads has a device body, a fundamental resistor, and at least one trimming resistor. The device body has a surface with two testing pads and without resistance trimming pads. The fundamental resistor is formed in the device body. The at least one trimming resistor is formed in the device body and connected to the fundamental resistor in series between the two testing pads. Residuals of at least one fusible wire that has been fused are connected to the at least one trimming resistor.

### CROSS REFERENCE TO RELATED APPLICATIONS

The present application claims priority to Taiwan application No. 112106795, filed on Feb. 23, 2023, the content of which is hereby incorporated by reference in its entirety.

### BACKGROUND OF THE INVENTION

### 1. Field of the Invention

The present invention relates to a semiconductor device, and more particularly to a semiconductor device without resistance trimming pads.

### 2. Description of Related Art

A conventional resistance trimming process is described herein. With reference to FIG. 12, a wafer 40 is provided. The wafer 40 has undergone a variety of semiconductor processes to have integrated circuits of multiple semiconductor devices 41. For conciseness in description, an X-Y-Z Cartesian coordinate system is depicted in FIG. 12. The positions of the semiconductor devices 41 are arranged in an array on the X-Y plane. Multiple X-axis scribe lines L1 and multiple Y-axis scribe lines L2 are defined on the surface of the wafer 40. Any one of the semiconductor devices 41 is located within a region enclosed by two adjacent X-axis scribe lines L1 and two adjacent Y-axis scribe lines L2.

Multiple resistance trimming pads 42, two testing pads 43, multiple fusible wires 44 and other pads (not shown in the drawings) for outward electrical connection are arranged on the surface of each semiconductor device 41. Each semiconductor device 41 at least has a fundamental resistor and multiple trimming resistors for implementing the purpose of impedance matching. It is understandable that forming a resistor layout in the wafer 40 by semiconductor processes is the common knowledge in the art. For conciseness in description, with reference to an example shown in FIG. 13, each semiconductor device 41 has four resistance trimming pads 42, three trimming resistors RT, and three fusible wires 44 that are illustrated as an equivalent circuit and symbols.

On the surface of each semiconductor device 41, one fusible wire 44 is connected between two adjacent resistance trimming pads 42. One testing pad 43 is connected to the other testing pad 43 through the fundamental resistor RB, the fusible wires 44, and the resistance trimming pads 42. The resistance trimming resistors RT are respectively connected to the fusible wires 44 in parallel. Under the foregoing connection state, the trimming resistors RT are electrically connected to the fundamental resistor RB, and are respectively short-circuited by the fusible wires 44.

In order to measure and trim the resistance property of each semiconductor device 41, the wafer 40 can be mounted to a tester. The tester has a probe card with multiple probes. The probes respectively contact the testing pads 43 and the resistance trimming pads 42 on the surface of each semiconductor device 41. Because the trimming resistors RT are respectively short-circuited by the fusible wires 44, the measured resistance from the two testing pads 43 of each semiconductor device 41 is equivalent to the resistance of the fundamental resistor RB. At that time, if the measured resistance of each semiconductor device 41 is too low to meet the impedance matching, the tester will apply a current through two adjacent resistance trimming pads 42 of each corresponding semiconductor device 41. The current will directly flow through the corresponding fusible wire 44 which is connected between such two adjacent resistance trimming pads 42. For the fusible wire 44, the current is as a short-circuit current. The heat caused by the current passing through the fusible wire 44 will fuse and interrupt the fusible wire 44. Then, the wafer 40 will be sawed along the X-axis scribe lines L1 and the Y-axis scribe lines L2. The semiconductor devices 41 will be separated from each other, and each semiconductor device 41 becomes a die.

With reference to FIG. 14, in the die of each semiconductor device 41, because one of the fusible wires 44 is fused and interrupted, the fundamental resistor RB is electrically connected to such fusible wire 44 in series. So the measured resistance from the two testing pads 43 is a whole resistance of the fundamental resistor RB and the trimming resistor RT, rather than the resistance of the fundamental resistor RB only. Hence, the purposes of resistance trimming and impedance matching will be achieved.

After the resistance trimming process as mentioned above, only when it is confirmed that the resistance of each semiconductor device 41 (such as the measured resistance from the two testing pads 43) is fixed, and there is no need to trim the resistance any more, the wafer 40 can be sawed to singulate the semiconductor devices 41. Namely, when the resistance trimming process is finished, the resistance trimming pads 42 do not have a substantive effect. However, the resistance trimming pads 42 still remain on the surface of each semiconductor device 42 and form a part of each semiconductor device 41. So the resistance trimming pads 42 occupying the surface area of each semiconductor device 41 will cause some problems. For example, a part of the surface area of each semiconductor device 41 is occupied by the resistance trimming pads 42, such that the entire surface area of each semiconductor device 41 cannot be reduced effectively. And accordingly, the space utilization of the wafer 40 is limited.

### SUMMARY OF THE INVENTION

An objective of the present invention is to provide a semiconductor device without the resistance trimming pads, to overcome the problems caused by the resistance trimming pads remaining on the conventional semiconductor device.

The semiconductor device of the present invention has a device body, a fundamental resistor, and at least one trimming resistor. The device body has a surface with two testing pads and without resistance trimming pads. The fundamental resistor is formed in the device body. The at least one trimming resistor is formed in the device body and connected to the fundamental resistor in series between the two testing pads. Residuals of at least one fusible wire that has been fused are connected to the at least one trimming resistor.

The semiconductor device of the present invention never includes the resistance trimming pads which occupy the space. Compared with the prior art, the surface area of the semiconductor device of the present invention can be effectively reduced, such that the die of the semiconductor device of the present invention can be downsized. Besides, from the perspective on a wafer, because each semiconductor device is downsized, the surface of the wafer has a relatively enlarged area available for use. So the space utilization of the wafer is much more flexible.

### BRIEF DESCRIPTION OF THE DRAWINGS

FIG. 1 is a schematic top view of a wafer including the semiconductor devices of the present invention;

FIG. 2 is a schematic side view of a wafer including the semiconductor devices of the present invention;

FIG. 3 is a schematic top view showing the connection of a resistor and a fusible wire of the semiconductor device of the present invention;

FIG. 4 is an equivalent circuit diagram for the semiconductor device of the present invention;

FIG. 5 is a schematic diagram showing the electric connection of a tester and the semiconductor device for the present invention;

FIG. 6 is a schematic diagram showing a current applied to two resistance trimming pads for the present invention;

FIG. 7 is an equivalent circuit diagram showing the fusible wire that has been fused is being interrupted for the present invention;

FIG. 8 is a schematic top view showing the residuals of the fusible wire that has been fused and interrupted for the present invention;

FIG. 9 is an equivalent circuit diagram showing the connection of the fundamental resistor, the trimming resistors, and the fusible wires of an embodiment of the semiconductor device of the present invention;

FIG. 10 is an equivalent circuit diagram showing the connection of the fundamental resistor, the trimming resistor, and the fusible wire of another embodiment of the semiconductor device of the present invention;

FIG. 11 is a schematic perspective view showing a resistor configuration of the semiconductor device of the present invention;

FIG. 12 is a schematic top view of a conventional wafer including conventional semiconductor devices;

FIG. 13 is an equivalent circuit diagram of a conventional semiconductor device included in the conventional wafer; and

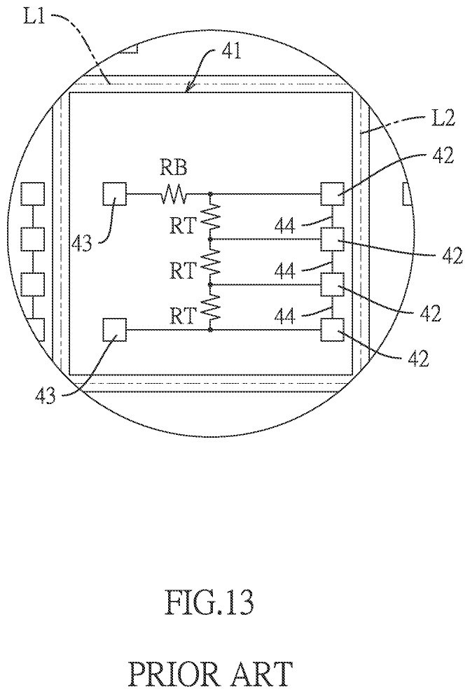

FIG. 14 is an equivalent circuit diagram of the conventional semiconductor device.

### DETAILED DESCRIPTION OF PREFERRED EMBODIMENT(S)

The structure as well as the resistance trimming process of the semiconductor device of the present invention are described below. Please note that the contents in the drawings, such as component sizes, shapes, ratios, and so on, are schematically illustrated for reference only.

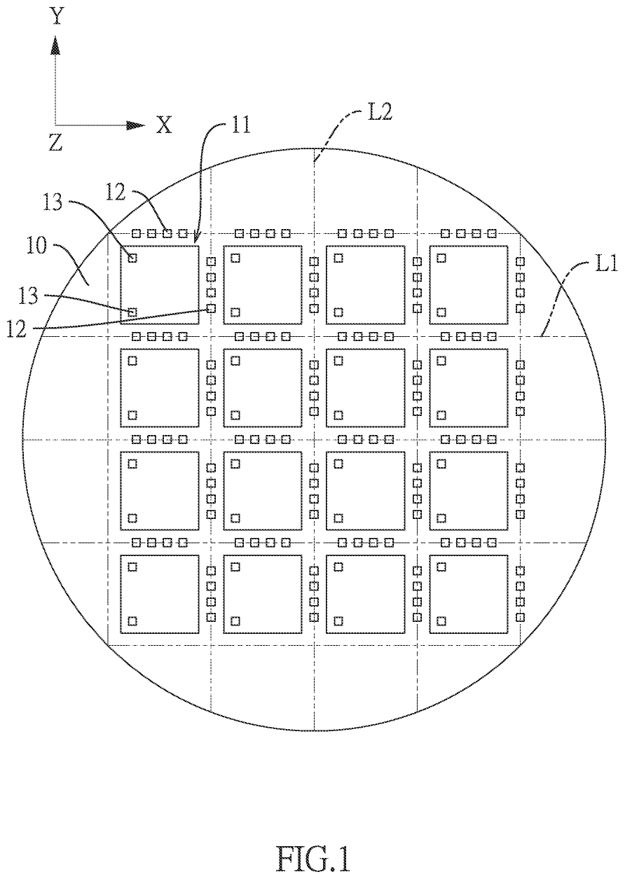

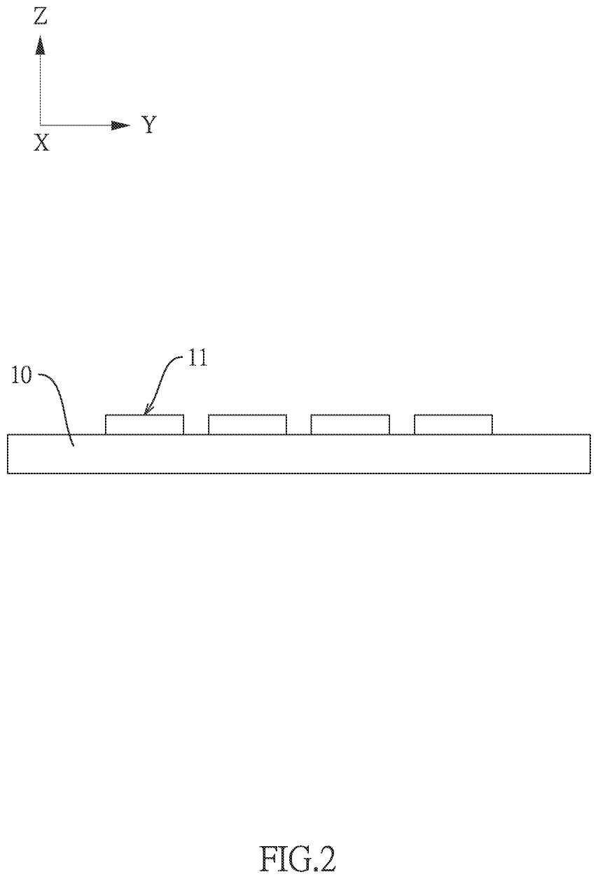

STEP S01: A wafer is provided. With reference to FIG. 1 and FIG. 2, the wafer 10 has undergone a variety of semiconductor processes to have integrated circuits of multiple semiconductor devices 11. For conciseness in description, an X-Y-Z Cartesian coordinate system is depicted in FIG. 1 and FIG. 2. The positions of the semiconductor devices 11 are arranged in an array arrangement on the X-Y plane. Multiple X-axis scribe lines L1 and multiple Y-axis scribe lines L2 are defined on the surface of the wafer 10. Any one of the semiconductor devices 11 is located within a region enclosed by two adjacent X-axis scribe lines L1 and two adjacent Y-axis scribe lines L2.

It is understandable that the entire integrated circuit of each semiconductor device 11 is made based on a designated specification and functions to have a resistor layout. The resistor layout may implement a purpose of impedance matching as an example. The present invention focuses on the resistor layout.

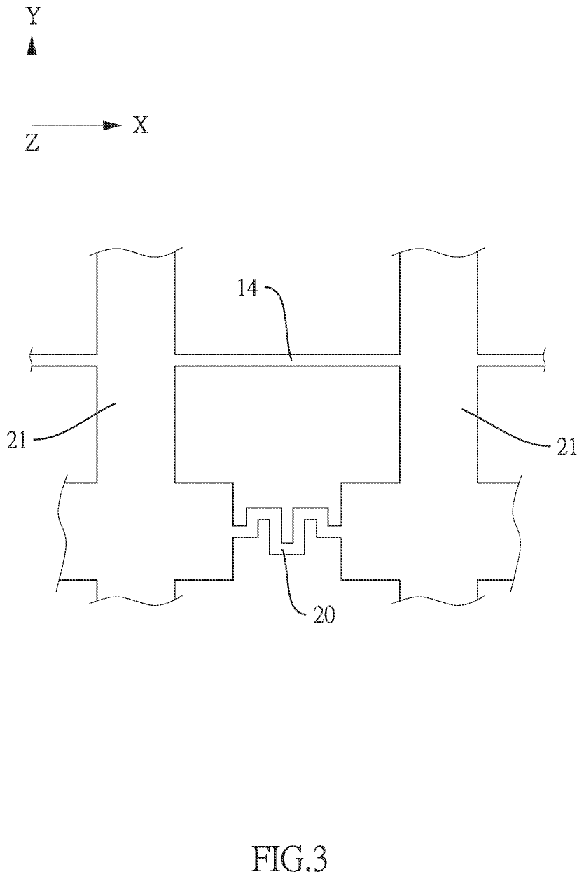

Forming the resistor layout in the wafer 10 by semiconductor processes is the common knowledge in the art. For example, one or multiple resistors can be formed in one layer of each semiconductor device 11 of the wafer 10, or multiple resistors can be respectively formed in multiple layers of each semiconductor device 11 of the wafer 10. With reference to FIG. 3 showing a resistor 20 as an example, the resistor 20 is a conductor providing the resistance property. The resistor 20 can be electrically connected to other parts of the wafer 10 or the semiconductor device 11 through a wire 21 and/or a conductive via along Z-axis. The conductor can be, but is not limited to, a copper sheet. The resistance property of the conductor is basically determined by the material, the cross-sectional area, and length of the conductor. In general, the conductor with smaller cross-sectional area or longer length will have higher resistance. Besides, the resistor 20 can have a bending shape as shown in FIG. 3, but the shape of the resistor 20 is not limited to the bending shape.

In an embodiment of the present invention, with reference to FIG. 1, multiple resistance trimming pads 12 for each semiconductor device 11 are arranged on the X-axis scribe lines L1 and/or the Y-axis scribe lines L2 of the wafer 10. The resistance trimming pads 12 are separated from each other. In other words, the resistance trimming pads 12 are distributed outside of each semiconductor device 11 and form no part of each semiconductor device 11.

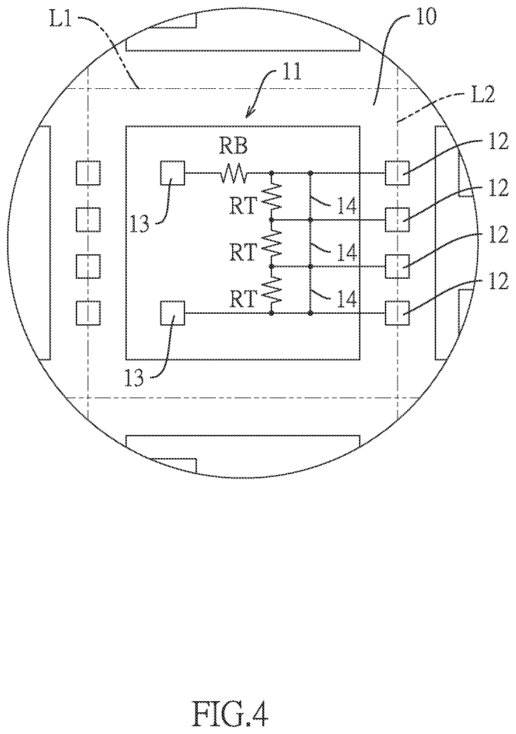

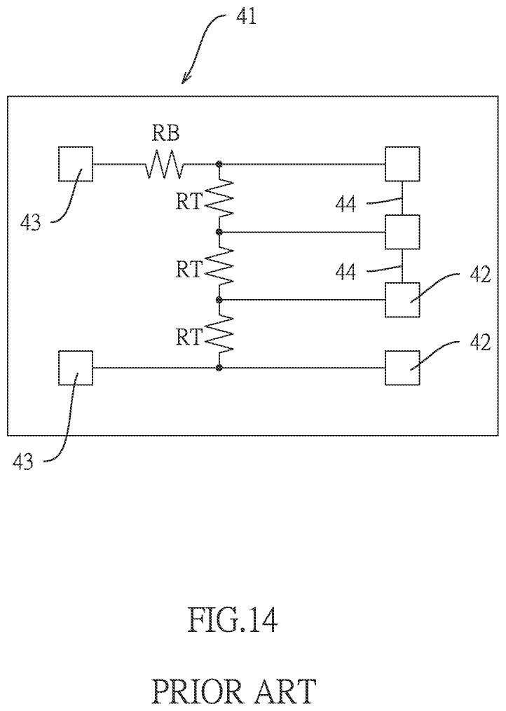

With reference to FIG. 1 and FIG. 4, in the wafer 10, each semiconductor device 11 has two testing pads 13, a fundamental resistor RB, at least one trimming resistor RT, and at least one fusible wire 14. The testing pads 13 may be arranged on the surface of the semiconductor device 11 and separated from each other. There are also other pads (not shown in the drawings) arranged on the surface of the semiconductor device 11 for outward electrical connection. The fusible wire 14 can be, but is not limited to, an aluminum wire. The fusible wire 14 can have a straight shape, but the shape of the fusible wire 14 is not limited to the straight shape. As mentioned above, forming the resistor 20, the wire 21, the conductive via, and layout in a wafer 10 is the common knowledge in the art. For conciseness in description, the fundamental resistor RB, the at least one trimming resistor RT, and the at least one fusible wire 14 as shown in FIG. 14 are illustrated as equivalent circuit and symbols.

In each semiconductor device 11, the fundamental resistor RB and the at least one fusible wire 14 are electrically connected in series between the two testing pads 13. The at least one fusible wire 14 is electrically connected between two of the resistance trimming pads 12, and electrically connected to the at least one trimming resistor RT in parallel. In a first embodiment of the present invention, as shown in FIG. 4, each semiconductor device 11 comprises multiple trimming resistors RT and multiple fusible wires 14. There are four resistance trimming pads 12, three trimming resistors RT, and three fusible wires 14 as shown in FIG. 4 as an example. The fundamental resistor RB and the fusible wires 14 are electrically connected in series between the two testing pads 13. The fusible wires 14 are electrically connected to the trimming resistors RT in parallel respectively. Under the foregoing connection state, although the trimming resistors RT are electrically connected to the fundamental resistor RB, the trimming resistors RT are respectively short-circuited by the fusible wires 14.

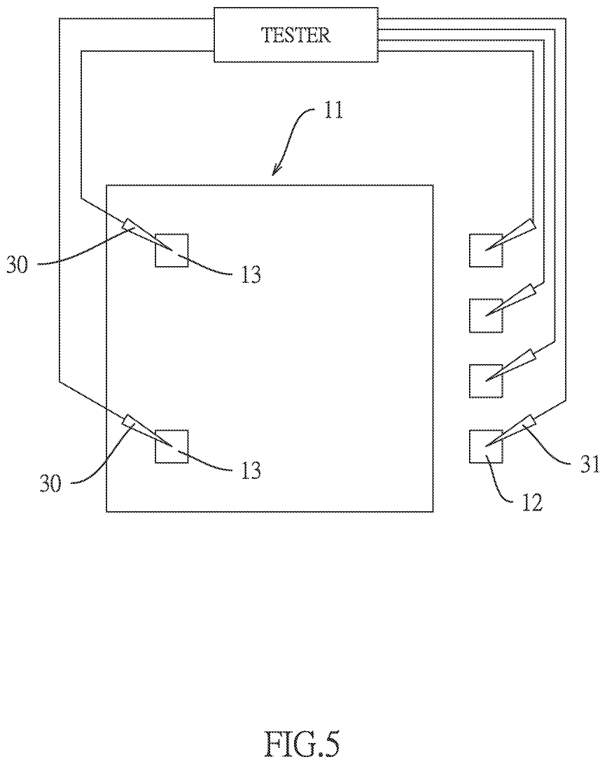

STEP S02: This step is to measure the resistance of each semiconductor device 11 via the two testing pads 13. In an embodiment of the present invention, the wafer 10 can be mounted to a tester. The tester has a probe card with multiple probes. A part of the probes may contact the testing pads 13 of the semiconductor devices 11. FIG. 4 and FIG. 5 schematically depict two probes 30 respectively contacting the two testing pads 13 of one of the semiconductor devices 11. As mentioned above, for each semiconductor device 11 as shown in FIG. 4, because the fundamental resistor RB is electrically connected to the fusible wires 14 in series, and the trimming resistors RT are respectively short-circuited by the fusible wires 14, the measured resistance of each semiconductor device 11 is equivalent to the resistance of the fundamental resistor RB.

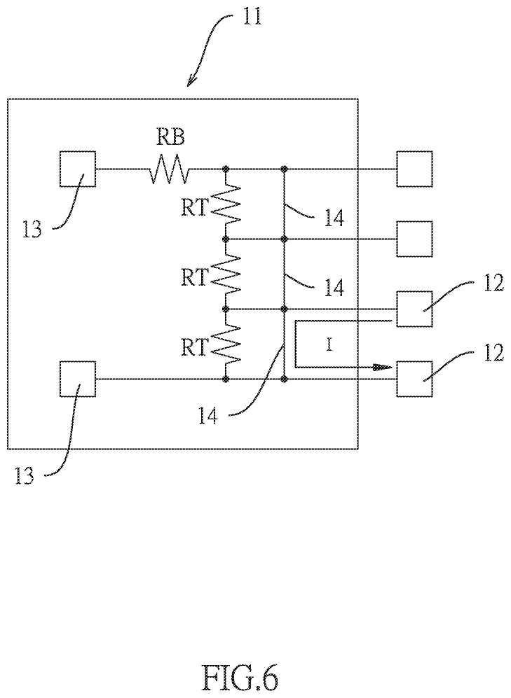

STEP S03: This step is to apply a current through two of the resistance trimming pads 12 of each corresponding semiconductor device 11 according to the measured resistance of each semiconductor device 11. In an embodiment of the present invention, FIG. 4 and FIG. 5 schematically depict other probes 31 of the tester respectively contacting the resistance trimming pads 12 of one of the semiconductor devices 11. If the measured resistance of the semiconductor device 11 is too low to meet the impedance matching, with reference to FIG. 5 and FIG. 6, the tester will apply a current I through two adjacent resistance trimming pads 12 of the corresponding semiconductor device 11. The current I will flow through one of the fusible wires 14 which is connected between the two adjacent resistance trimming pads 12. For the fusible wire 14, the current I is as a short-circuit current. The heat caused by the current I passing through the fusible wire 14 will fuse and interrupt the fusible wire 14. The following table lists examples of the specifications of the fusible wires 14 and corresponding current magnitudes to fuse and interrupt them.

| Specifications of fusible wire | Spec. 1 | Spec. 2 | Spec. 3 | Spec. 4 |
|---|---|---|---|---|
| Wire width (μm) | 35 | 55 | 75 | 95 |
| Cross-sectional area (μm²) | 105 | 165 | 225 | 285 |
| Current magnitude (A) | 5 | 7 | 9 | 10.5 |

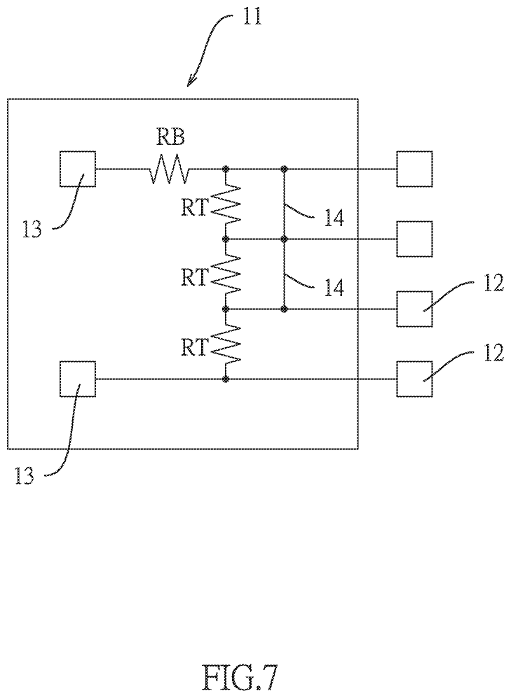

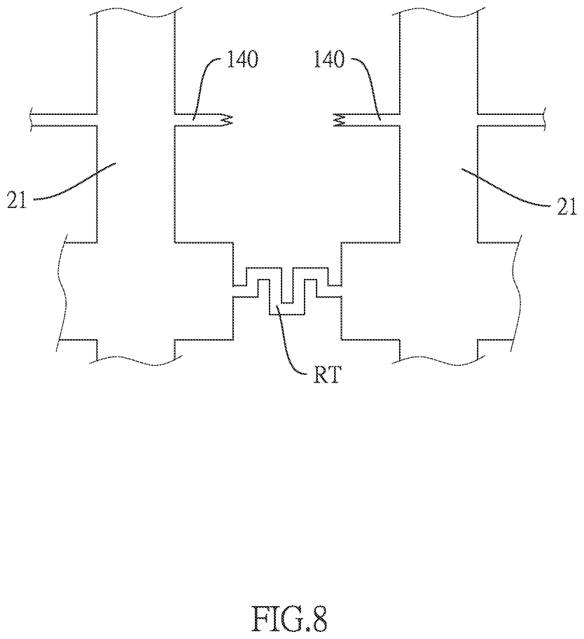

As a result, the fundamental resistor RB of each semiconductor device 11 is electrically connected to one of the trimming resistors RT in series. With reference to the equivalent circuit as shown in FIG. 7, the measured resistance of each semiconductor device 11 is changed from the resistance of the fundamental resistor RB (as measured in the forgoing STEP S02) to a whole resistance of the fundamental resistor RB and the trimming resistor RT. So the measured resistor of each semiconductor device 11 is increased. The purpose to trim the resistance for the semiconductor devices 11 is achieved. It can be deduced that when the whole resistance of the fundamental resistor RB and the trimming resistor RT fails to meet the impedance matching yet, other fusible wires 14 are standby to be fused and interrupted for increasing the measured resistance of each semiconductor device 11 until the measured resistance meets the impedance matching. In addition, in view of the substantial structure of the semiconductor device 11, after the fusible wire 14 is fused and interrupted, with reference to FIG. 8, residuals 140 of the fusible wire 14 that has been fused and interrupted are still connected to the corresponding trimming resistor RT.

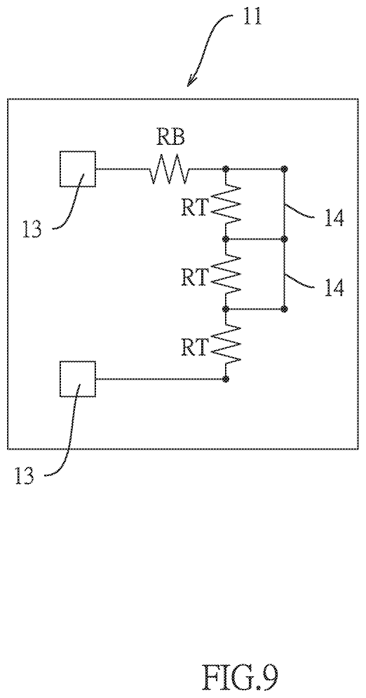

STEP S04: A singulation process is to singulate the semiconductor devices 11 of the wafer 10 by sawing the wafer 10 along the X-axis scribe lines L1 and the Y-axis scribe lines L2, such that each semiconductor device 11 becomes a die. Because the resistance trimming pads 12 are arranged on the X-axis scribe lines L1 and/or the Y-axis scribe lines L2, the resistance trimming pads 12 are removed while sawing. Hence, with reference to FIG. 9, each semiconductor device 11 does not have the resistance trimming pads 12 certainly.

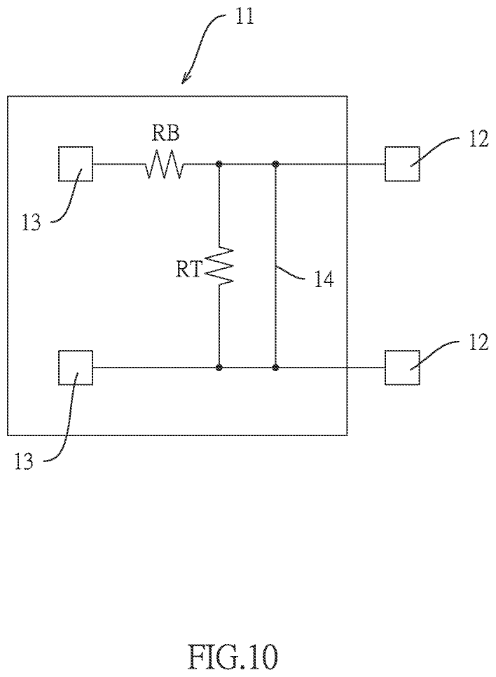

In STEP S01 of the foregoing first embodiment, each semiconductor device 11 comprises multiple trimming resistors RT and multiple fusible wires 14 as an example. So in STEP S03, the measured resistance of each semiconductor device 11 can be increased step by step by selecting one or more than one of the fusible wires 14 to fuse and interrupt. In a second embodiment of the present invention, with reference to FIG. 10, each semiconductor device 11 can have a single trimming resistor RT and a single fusible wire 14. So the measured resistance from the two testing pads 13 can be switched directly by fusing and interrupting such single fusible wire 14 after STEP S03.

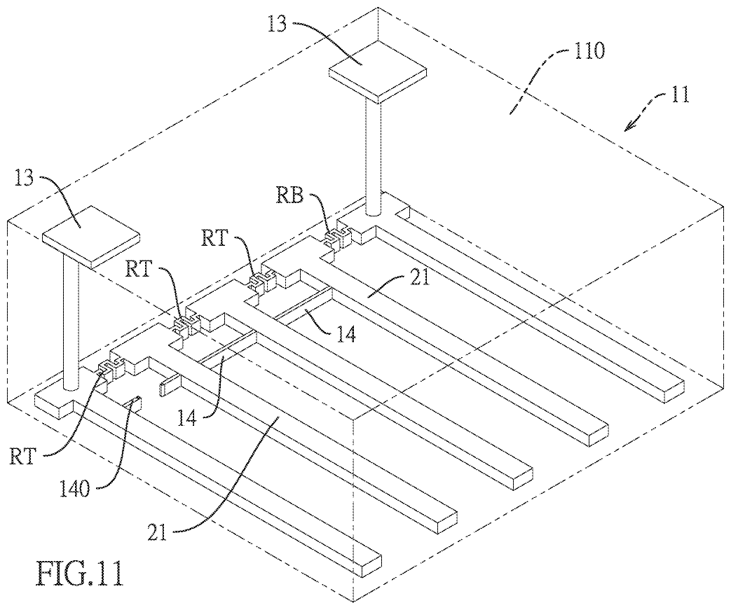

In summary of the foregoing resistance trimming process, with reference to FIG. 9 and FIG. 11, the semiconductor device 11 of the present invention comprises a device body 110, a fundamental resistor RB, and at least one trimming resistor RT. Because the resistance trimming pads 12 as shown in FIG. 1 are removed while sawing the wafer 10 in the singulation process, the semiconductor device 11 of the present invention never includes the resistance trimming pads 12.

The device body 110 has a surface with two testing pads 13. It is understandable that there are also other pads (not shown in the drawings) arranged on the surface of the device body 110 for outward electrical connection. The fundamental resistor RB and the at least one trimming resistor RT are formed in the device body 110 and adapted to implement the impedance matching. The at least one trimming resistor RT and the fundamental resistor RB are connected in series and between the two testing pads 13. With reference to FIG. 8, the at least one trimming resistor RT is connected to the residuals 140 of the at least one fusible wire 14 that has been fused and interrupted. So the residuals 140 remain within the device body 110.

As the first embodiment of the resistance trimming process as mentioned above, with reference to FIG. 7, when all of the fusible wires 14 are fused and interrupted, all of the trimming resistors RT in the semiconductor 11 are connected with the residuals 140 of the fusible wires 14. Or when only one or only some of the fusible wires 14 are fused and interrupted, only the corresponding trimming resistor RT in the semiconductor 11 is connected with the residuals 140. The rest of the fusible wires 14 that has/have not been fused and interrupted yet is/are still connected to the corresponding trimming resistor(s) RT in parallel, such that said corresponding trimming resistor(s) RT is/are still short-circuited by said fusible wire(s) 14 that has/have not been fused and interrupted yet.

In conclusion, the present invention has the following effects:

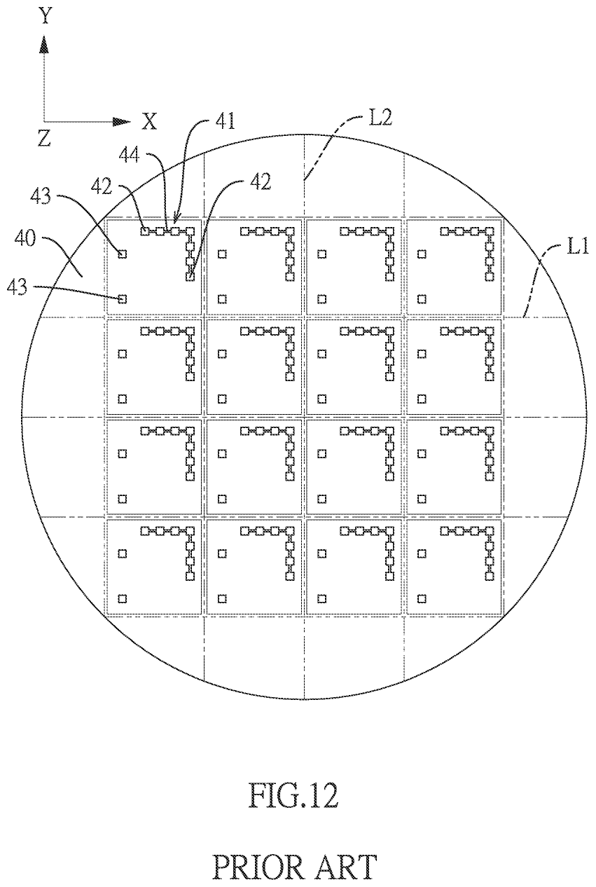

1. The resistance trimming pads 12 are removed while sawing the wafer 10 in the singulation process. With reference to FIG. 9 of the present invention in comparison with FIG. 14 of the prior art, the semiconductor device of the present invention never includes the resistance trimming pads 12,42. That can effectively reduce the surface area of the semiconductor device 11 to downsize the die of the semiconductor device 11 of the present invention. Besides, with reference to FIG. 1 of the present invention in comparison with FIG. 12 of the prior art, because the die of the semiconductor device 11 of the present invention is downsized, the surface of the wafer 10 has a relatively enlarged area available for use. So the space utilization of the wafer 10 will become much more flexible. For example, one wafer 10 may contain more semiconductor devices 11 to increase the production capacity, or other components may be further formed on the wafer 10.

2. As the above-mentioned embodiment, each semiconductor device 11 in the wafer 10 may comprise multiple trimming resistor RT and multiple fusible wires 14. So in STEP S03, the measured resistance from the two testing pads 13 of each semiconductor device 11 can be increased step by step by selecting one or some of the fusible wires 14 to fuse and interrupt. By doing so, the resistance trimming mechanism of the present invention is quite flexible.

3. In the present invention, when the wafer 10 is mounted to the tester, the probes of the tester respectively contact the testing pads 13 and the resistance trimming pads 12 of the semiconductor devices 11 at the same time. So the measurement and trimming for the resistance of the semiconductor devices 11 can be performed collaboratively to have high efficiency.

Even though numerous characteristics and advantages of the present invention have been set forth in the foregoing description, together with details of the structure and function of the invention, the disclosure is illustrative only. Changes may be made in detail, especially in matters of shape, size, and arrangement of parts within the principles of the invention to the full extent indicated by the broad general meaning of the terms in which the appended claims are expressed.

What is claimed is:

1. A semiconductor device without resistance trimming pads, comprising:
a device body having a surface with two testing pads and without resistance trimming pads;
a fundamental resistor formed in the device body; and
at least one trimming resistor formed in the device body and connected to the fundamental resistor in series between the two testing pads, wherein residuals of at least one fusible wire that has been fused are connected to the at least one trimming resistor.

2. The semiconductor device as claimed in claim 1 comprising a plurality of the trimming resistors, wherein at least one of the plurality of trimming resistors is connected to the residuals of the at least one fusible wire that has been fused.

3. The semiconductor device as claimed in claim 1 further comprising another at least one trimming resistor formed in the device body and short-circuited by another at least one fusible wire.

4. The semiconductor device as claimed in claim 1, wherein the at least one trimming resistor is a single one and connected to the residuals of the at least one fusible wire that has been fused.
